(19) United States
(12) Patent Application Publication
(10) Pub. No.: US 2006/0227236 A1
(43) Pub. Date: Oct. 12, 2006

(54) Camera module and method of manufacturing the same

(76) Inventor: Jae Youn Pak, Seoul (KR)

Correspondence Address: STANZIONE & KIM, LLP, 919 18TH STREET, N.W., SUITE 440, WASHINGTON, DC, 20006, US

(21) Appl. No.: 11/359,587

(22) Filed: Feb. 23, 2006

(30) Foreign Application Priority Data
Apr. 8, 2005 (KR) 2005-29388

(51) Int. Cl. H04N 5/225

(52) U.S. Cl. 348/340; 324/754; 348/374

(57) ABSTRACT

The present invention relates to a camera module, and more particularly, to a camera module which is miniaturized by changing the structure of a housing joined to a PCB on which a standardized image sensor is wire-bonded and a method of manufacturing the camera module. The camera module includes a PCB to which an image sensor is connected by a wire bonding section; and a housing that holds a lens section. The housing includes a joining section that is joined to the side where the wire bonding section of the PCB is not formed; and a step section that is formed to recede in a portion corresponding to the wire bonding section of the PCB.

### CROSS-REFERENCE TO RELATED APPLICATIONS

The application claims the benefit of Korea Patent Application No. 2005-0029388 filed with the Korea Industrial Property Office on Apr. 8, 2005, the disclosure of which is incorporated herein by reference.

### BACKGROUND OF THE INVENTION

1. Field of the Invention

The present invention relates to a camera module, and more particularly, to a camera module which is miniaturized by changing the structure of a housing joined to a PCB on which a standardized image sensor is wire-bonded and a method of manufacturing the camera module.

2. Description of the Related Art

In general, a camera module is an imaging device which is used in a video camera, a digital camera, a PC camera, a mobile phone, and a PDA for the recognition of an image. A miniaturized camera module is built in such products.

Recently, as the functions of a mobile phone have become diverse and complex, it is required that parts and devices which are installed and mounted therein to perform various functions should be miniaturized and disposed properly to effectively utilize the inner space thereof.

Therefore, the miniaturization of such parts and devices has gradually accelerated. Further, the miniaturization of the camera module should be also accomplished because a larger number of parts should be mounted on the multiifunctional camera module.

The camera module includes a sensor section in which an image sensor is wire-bonded on a PCB; a lens section which is composed of a plurality of lenses to focus light on the image sensor; and a housing which holds the lens section and that is put on the upper portion of the lens section so as to separate the sensor section. In general, the sensor section and the housing holding the lens section are coupled to each other so as to form a module.

The image sensor is an element which detects information of an object to convert into an electrical video signal. The image sensor is divided into an image pickup tube and a solid image sensor.

As the image pickup tube, a vidicon, plumbicon, and saticon are used. As the solid image sensor, a CMOS (complementary metal oxide semiconductor) and CCD (charge coupled device) are used.

The solid image sensor (hereinafter, referred to as ‘the image sensor’) is used as an image sensor in a camera module according to the present invention.

Typically, the image sensor is a component which has a significant influence on the size of a camera module. As a pixel value (resolution) increases, the size thereof increases.

In a small product such as a mobile phone having a camera built therein, a camera module in which the image sensor is modulized is incorporated. In a 300-thousand-pixel product, a camera module having a size of about 6.7×6.7 mm² is being widely used, as shown in FIG. 1A.

In the detailed descriptions and drawings of the present invention, a camera module according to the related art and a camera module according to the present invention, which are manufactured by using image sensors having the same size as each other (300-thousand-pixel image sensor), will be compared and described.

The camera module according to the related art, which is manufactured by using the standardized image sensor, and a method of manufacturing the camera module will be described with reference to FIGS. 1A to 1C.

Referring to FIG. 1A, a 300-thousand-pixel image sensor 110 is attached on a PCB 101 through a general COB (chip on board) process. The image sensor 110 and the PCB 101 are electrically connected to each other by a wire bonding section 111.

Outside the wire bonding section 111, that is, on the edge of the PCB 101, a joining section (pad) 130 is formed so as to be joined to a joining section 122 (refer to FIG. 1B) which is the lower surface of the lateral wall of a housing 102 (refer to FIG. 1B).

Therefore, when the housing 102 is joined on the PCB 101 to form the camera module, the size of the PCB 101 should be secured by more than 6.7×6.7 mm², including the width between the wire bonding sections 111 and the width between the joining regions 130, in order not to have an influence on the wire bonding section 111.

The housing 102 attached on the joining region 130 of the PCB 101 has a lateral wall formed in four directions to correspond to the joining section 130 of the PCB 101, as shown in FIG. 1B. On the lower surface of the lateral wall, a joining section 122 is formed.

In the upper portion of the housing 102, a lens section holder 124 is formed, to which a lens section 120 (refer to FIG. 1C) is coupled. Inside the lower surface of the housing 102, an IR filter receiving groove 125 is formed, on which an IR filter 121 (refer to FIG. 1C) is attached.

FIG. 1c shows the structure of the camera module according to the related art, in which the PCB 101 to which the image sensor 110 is electrically connected, the housing 102, the IR filter 121, and the lens sections 120 are joined to each other.

Referring to FIG. 1C, the image sensor 110 is connected to the PCB 101 by the wire bonding section 111, the IR filter 121 is attached on the IR filter receiving groove 125 of the housing 102, and the lens section 120 is inserted and fixed to the lens section holder 124 of the housing 102. Then, a half-assembled housing assembly and a half-assembled PCB assembly are formed.

Next, an adhesive is applied to the joining section 122 of the housing 102 or the joining region 130 of the PCB 101 so that the housing 102 (half-assembled housing assembly) and the PCB 101 (half-assembled PCB assembly) are joined to each other. Then, the camera module is completed.

In the camera module manufactured in such a manner, a space is present between the joining section 130 and the wire bonding section 111 on the PCB 101, as shown in FIG. 1C.

Therefore, when the camera module according to the related art is built in a limited space such as the inner space of a mobile phone, a number of parts such as passive elements and chips for performing various functions cannot be mounted or installed together, or a separate space should be secured.

Further, since the size of new mobile phones gradually becomes miniaturized and slim, miniaturized parts are mounted or installed in the new mobile phones. As a result, the camera module according to the related art is required to be miniaturized.

### SUMMARY OF THE INVENTION

An advantage of the present invention is that it provides a camera module, in which the structure of a housing joined to the upper portion of a PCB is changed to miniaturize a conventional camera module when a standardized image sensor is used to manufacture the camera module, and parts and elements for performing various functions are mounted or installed together in a space secured by the miniaturization of the camera module to thereby utilize the limited space effectively.

Additional aspects and advantages of the present general inventive concept will be set forth in part in the description which follows and, in part, will be obvious from the description, or may be learned by practice of the general inventive concept.

According to an aspect of the invention, a camera module includes a PCB to which an image sensor is connected by a wire bonding section; and a housing that holds a lens section. The housing includes a joining section that is joined to the side where the wire bonding section of the PCB is not formed; and a step section that is formed to recede in a portion corresponding to the wire bonding section of the PCB.

According to another aspect of the invention, the camera module further includes an adhesive that joins the PCB to the joining section of the housing and that fills the space between the wire bonding section and the step section of the housing.

According to a further aspect of the invention, a method of manufacturing a camera module includes forming a step section of a housing in a portion corresponding to a wire bonding section of a PCB, the step section being formed to recede, and forming a joining section of the housing in a portion corresponding to the side where the wire bonding section of the PCB is not formed; joining the housing onto the PCB by applying an adhesive to the joining section; and filling the adhesive in the space between the wire bonding section and the step section.

According to a still further aspect of the invention, the method of manufacturing a camera module further includes fixing the housing to the PCB by using a pressing jig after filling the adhesive.

According to a still further aspect of the invention, the method of manufacturing a camera module further includes thermally hardening the adhesive filled in the space, with the housing and PCB being fixed by the pressing jig, after fixing the housing.

According to a still further aspect of the invention, the method of manufacturing a camera module further includes flattening the lateral surface of the housing by using a cutting jig in order to remove the adhesive exposed outside the space between the wire bonding section and the step section of the housing after thermally hardening the adhesive.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a plan view illustrating a PCB to which an image sensor according to the related art is electrically connected by wire bonding sections;

FIG. 1B is a perspective bottom view illustrating a housing which is joined on the PCB of FIG. 1A;

FIG. 1C is a cross-sectional view illustrating a camera module which is formed by joining the PCB and housing of FIGS. 1A and 1B;

FIG. 2A is a plan view illustrating a PCB to which an image sensor according to the present invention is electrically connected by wire bonding sections;

FIG. 2B is a perspective bottom view illustrating a housing which is joined on the PCB of FIG. 2A;

FIG. 2C is a cross-sectional view illustrating a camera module which is formed by joining the PCB and housing of FIGS. 2A and 2B;

FIG. 3 is a cross-sectional view illustrating the camera module, showing a state where an adhesive is filled in the space between the wire bonding section and a step section of the housing of FIGS. 2A and 2B so as to be exposed outside;

FIG. 4A is a plan view illustrating a PCB to which an image sensor according to a first modified embodiment of the invention is electrically connected by wire bonding sections;

FIG. 4B is a perspective bottom view illustrating a housing which is joined on the PCB of FIG. 4A;

FIG. 5A is a plan view illustrating a PCB to which an image sensor according to a second modified embodiment of the invention is electrically connected by wire bonding sections;

FIG. 5B is a perspective bottom view illustrating a housing which is joined on the PCB of FIG. 5A; and

FIG. 6 is a flow chart showing a method of manufacturing the camera module according to the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

A camera module according to the present invention is composed of a PCB 1 on which an image sensor 10 is wire-bonded; a housing 2 which holds a lens section 20 and has a joining section 22 and step section 23 formed; and an adhesive 3 which joins the PCB to the joining section 22 of the housing and fills a space formed by the step section 23 of the housing 2. The joining section 22 is joined to the side where a wire bonding section 11 of the PCB 1 is not present.

Hereinafter, preferred embodiments of the present invention will be described in detail with reference to the accompanying drawings.

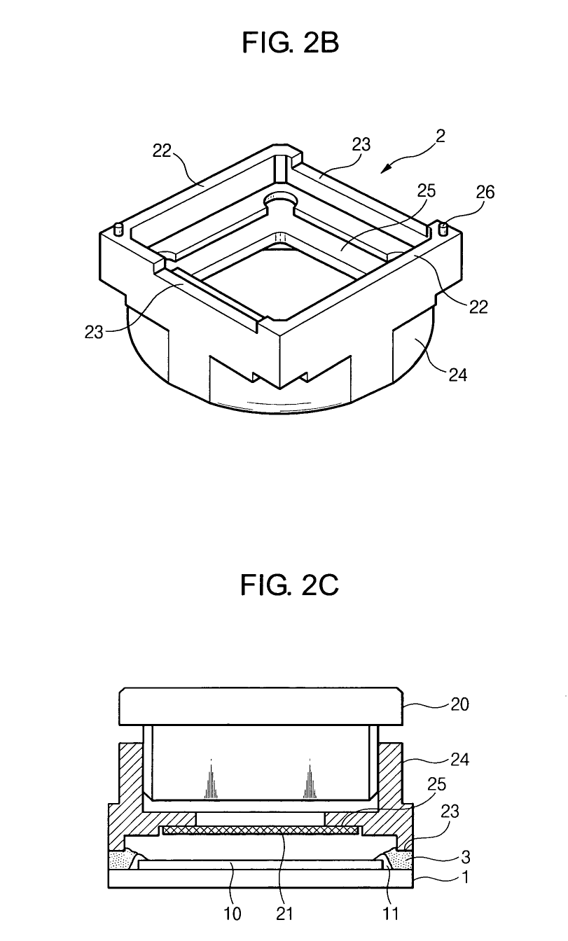

FIG. 2A is a plan view illustrating a PCB 1 to which an image sensor 10 according to the present invention is electrically connected by wire bonding sections 11, showing a state where the image sensor 10 is electrically connected to the PCB 1 by the wire bonding sections 11 through a general COB process.

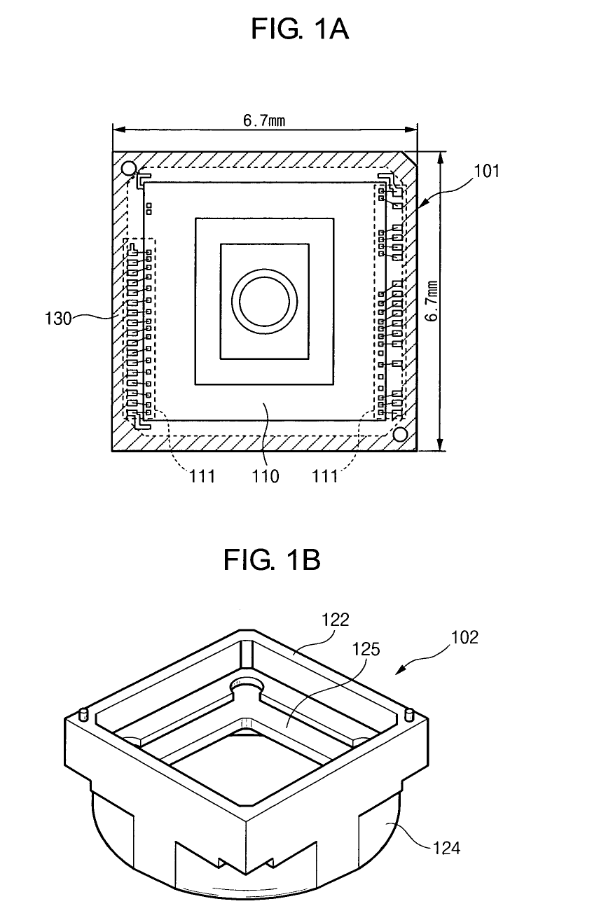

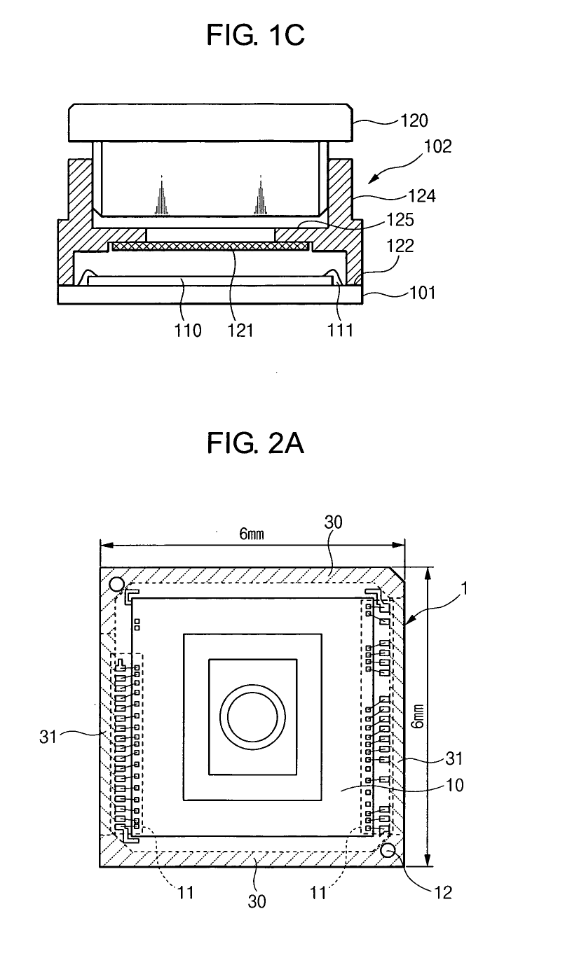

Hereinafter, the image sensor 10 according to the present embodiment has the same pixel value and size as the image sensor 110 shown in FIG. 1A.

Referring to FIG. 2A, the image sensor 10 is attached on the PCB 1, the image sensor 10 and the PCB 1 are electrically connected to each other by the wire bonding sections 11, and the wire bonding sections 11 are formed in the left and right side of the image sensor 10.

On the edge of the PCB 1, filling regions 31, in which an adhesive 3 is filled, are formed in the sides where the wire bonding sections 11 are present, and joining regions 30 are formed in the sides where the wire bonding sections 11 are not present. The joining regions 30 are joined to joining sections 22 (refer to FIG. 2B) which are the lower surfaces of the lateral walls of a housing 2 (refer to FIG. 2B).

In the diagonal corners of the PCB 1, a fixing hole 12 is formed, into which a fixing projection 26 (refer to FIG. 2B) of the housing 2 is inserted so as to be fixed.

Referring to FIG. 2a, the area of the PCB 1 can be reduced by substantially removing the joining section 130 which is present in the outer edge of the wire bonding section 111 of the PCB 101 according to the related art. Further, since the width between the lateral walls of the housing 2 which is joined to the upper portion of the miniaturized PCB 1 is reduced up to the wire bonding section 11, a camera module can be miniaturized even though a standardized image sensor 10 is used. In addition, as the camera module is miniaturized, a larger number of parts such as various passive elements or chips for performing various functions can be mounted in the secured space of the PCB and the secured inner space of a product.

Therefore, although the width between the wire bonding sections 11 and the width between the joining regions 30 are considered, it is possible to form the camera module of which the PCB 1 shown in FIG. 2A has a size of 6.0×6.0 mm².

FIG. 2B is a perspective bottom view illustrating the housing 2 which is attached to the joining region 30 of the PCB 1.

Referring to FIG. 2B, the housing 2 has lateral walls formed in four directions so as to be joined on the PCB 1. On the lower surface of the lateral wall corresponding to the wire bonding section 11 of the PCB among the lateral walls, a step section 23 is formed so as to recede. In a portion corresponding to the side where the wire bonding section 11 of the PCB 1 is not present, that is, on the lower surface of the lateral wall corresponding to the joining region 30 of the PCB 1, the joining section 22 is formed.

Preferably, the step section 23 of the housing 2 may be formed to have such a depth that the lower surface of the step section 23 does not come in contact (wire touch) with the wire bonding section 11 of the PCB 1 when the housing 2 and the PCB 1 are joined to each other. The length of the step section 23 can be properly adjusted or modified so as to correspond to the length of the wire bonding section 11.

In the upper portion of the housing 2, a lens section holder 24 is formed, to which a lens section 20 (refer to FIG. 2C) is coupled. Inside the lower surface of the housing 2, an IR filter receiving groove 25 is formed, to which an IR filter 21 (refer to FIG. 2C) is attached.

In the diagonal corners of the joining section 22 formed on the lower surface of the housing 2, the fixing projection 26 is formed to be inserted into the fixing hole 12 of the PCB 1 so as to be fixed.

FIG. 2C is a cross-sectional view illustrating a camera module in which the PCB 1 and the housing, shown in FIGS. 2A and 2B, are joined to each other, showing a state where the camera module is cut in the direction where the wire bonding section 11 is present in order to show that the wire bonding section 11 of the PCB and the step section 23 of the housing 2 are joined to each other.

As shown in FIG. 2A, the image sensor 10 is electrically connected on the PCB 1 by the wire bonding section 11. On the upper portion of the PCB 1, the housing 2 shown in FIG. 2B is joined by the adhesive 3.

The lens section 20 is inserted into the lens section holder 24 formed in the upper portion of the housing 2, and the IR filter 21 is attached to the IR filter receiving groove 25 formed inside the lower surface of the housing 2.

Referring to FIG. 2C, the step section 23 of the housing 2 is positioned in a portion corresponding to the wire bonding section 11 so that a space is formed between the wire bonding section 11 and the step section 23. The joining section 22 of the housing 2 is joined to the joining region 30 of the PCB 1, where the wire bonding section 11 is not formed, by the adhesive 3.

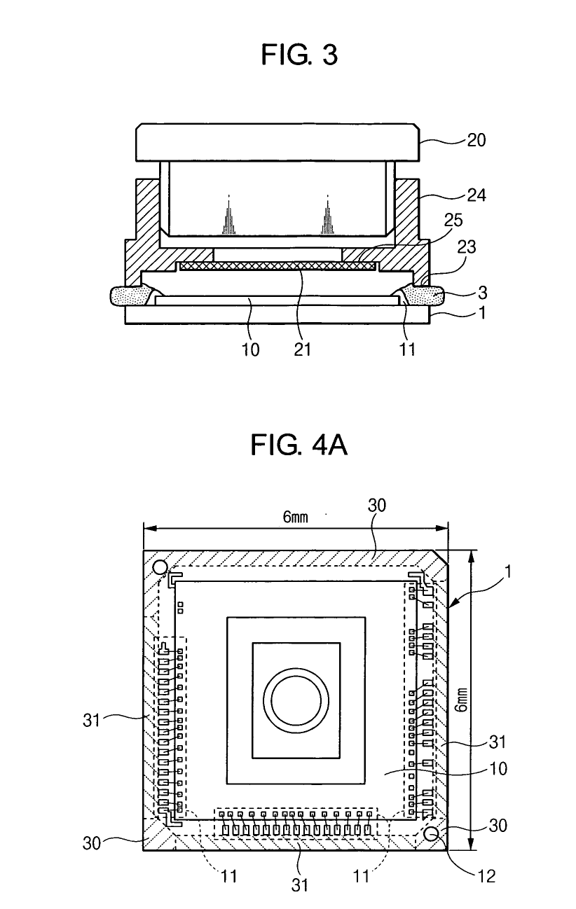

In the space, the black adhesive 3 is filled so that light does not penetrate through the inside of the camera module. As shown in FIG. 3, the adhesive 3 exposed to the outside of the space is removed by a cutting jig (not shown) for the surface treatment. Here, it is important that the adhesive 3 is applied at an appropriate pressure by using a nozzle (not shown) and the applied amount of adhesive 3 is properly adjusted so as not to have an influence on the image sensor 10 when the adhesive 3 is filled.

Preferably, the adhesive 3 filled in the space is an epoxy bond and has a viscosity of about 9000 cp and a thixotropic value of 4 to 5, where the adhesive does not drip down when applied to the space.

Thixotropic means a consistency that is gel-like at rest but fluid when agitated, so that resin adhered on a vertical surface by the dipping or resin soaked into a laminated material does not drip down or is not swept away. As the thixotropic index is high, the thixotropic property is strong. Generally, the thixotropic index is less than or equal to 5.

Since the high-viscosity epoxy adhesive 3 having a thixotropic index of 4 to 5 is applied to the space in the present embodiment, the housing 2 can be effectively sealed so that the epoxy adhesive 3 does not flows into the image sensor 10.

The epoxy adhesive 3 filled in the space may flow into the wire bonding section 11 so as to be applied. However, if the adhesive 3 flows into the image sensor 10 so as to be applied, it can be the cause of a defective camera module. Therefore, the adhesive 3 should be applied carefully.

On the other hand, when an epoxy adhesive having a thixotropic index of less than 4 is applied to the space, it is difficult to seal the housing 2 because the applied epoxy adhesive does not stay within the space but drips down. In some cases, when some of the epoxy adhesive flows into the image sensor 10 so as to be applied to a portion of the upper surface of the image sensor 10, a light-receiving area is reduced, which is also a cause of a defective camera module.

FIG. 3 is a cross-sectional view illustrating a camera module, showing a state where the adhesive 3 is filled in the space between the wire bonding section 11 and the step section 23 of the housing 2, shown in FIGS. 2A and 2B, so as to be exposed outside. FIG. 3 shows a state before the outside surface of the housing 2 is surface-treated after the adhesive 3 is filled in the space of the housing 2 shown in FIG. 2C.

Since the high-viscosity epoxy adhesive 3 is applied in the space between the wire bonding section 11 and the step section 23 of the housing 2, the applied adhesive 3 does not drip down but is maintained as it is, as shown in FIG. 3. The applied adhesive 3 hardens in a state where it projects outside.

If the adhesive 3 projecting outside the space is not removed, the size of the camera module increases as a result. When the camera module is installed in a small product, the area of the PCB 1 occupies as much as the projecting portion of the adhesive 3, so that the inner surface cannot be effectively utilized.

Therefore, in order to obtain a small-sized camera module, the surface treatment may be performed, in which the adhesive 3 projecting outside the space is removed by a cutting jig (not shown), serving as a cutting unit, to flatten the lateral surface of the housing 2 as shown in FIG. 2.

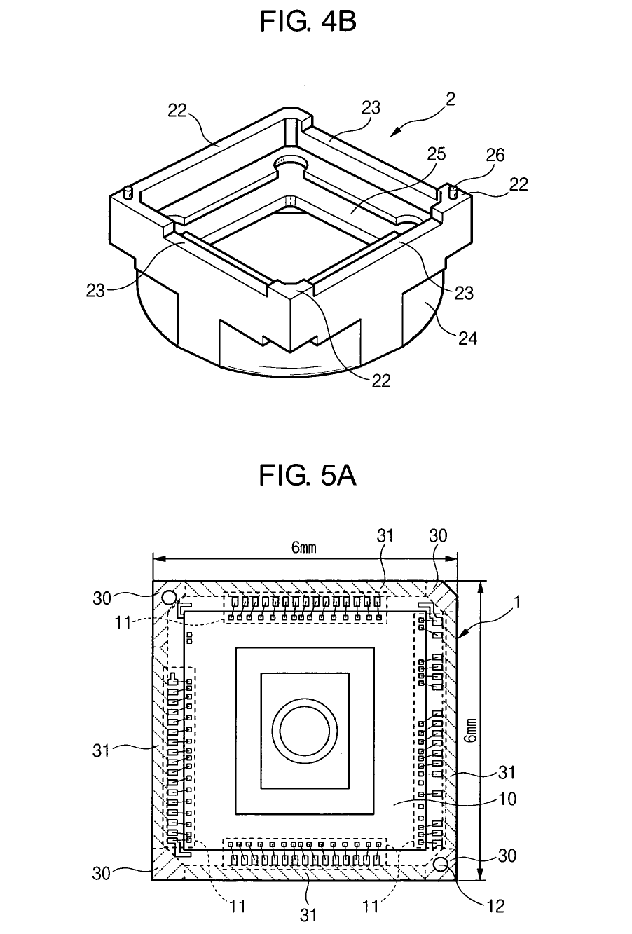

FIG. 4A is a plan view illustrating the PCB 1 in which an image sensor 10 according to a first modified embodiment of the invention is electrically connected by wire bonding sections 11, and FIG. 4B is a perspective bottom view illustrating a housing 2 which is joined on the PCB 1 of FIG. 4A. Hereinafter, the descriptions overlapped with those of the above-described embodiment will be omitted.

Referring to FIG. 4A, the image sensor 10 is attached on the PCB 1, the image sensor 10 and the PCB 1 are electrically connected by the wire bonding sections 11, and the wire bonding sections 11 are formed in three directions, that is, in the left, right, and lower sides of the image sensor 10.

On the edge of the PCB 1, filling regions 31, in which the adhesive 3 is filled, are formed in three directions where the wire bonding sections 11 are present, and a joining region 30 is formed in one direction where the wire bonding section 11 is not present. The joining region 30 is joined to a joining section 22 (refer to FIG. 4B) which is the lower surface of the lateral wall of the housing 2 (refer to FIG. 4B).

Referring to FIG. 4B, the housing 2 has lateral walls formed in four directions so as to be joined on the PCB 1, and step sections 23 are formed to recede in three directions on the lower surfaces of the lateral walls corresponding to the wire bonding sections 11 of the PCB 1 among the lateral walls. On the lower surface of the remaining lateral wall corresponding to the joining region 30 of the PCB 1, where the wire bonding section 11 of the PCB 1 is not formed, the joining section 22 is formed in the one remaining direction.

A camera module according to the first modified example of the present embodiment is the same as the embodiment shown in FIGS. 2A to 2C, except that the image sensor 10 is wire-bonded in three directions on the PCB 1. Further, in the first modified example, the space is increased, compared with the embodiment of the present invention. Therefore, the adhesive 3 should be additionally filled as much as the increased space.

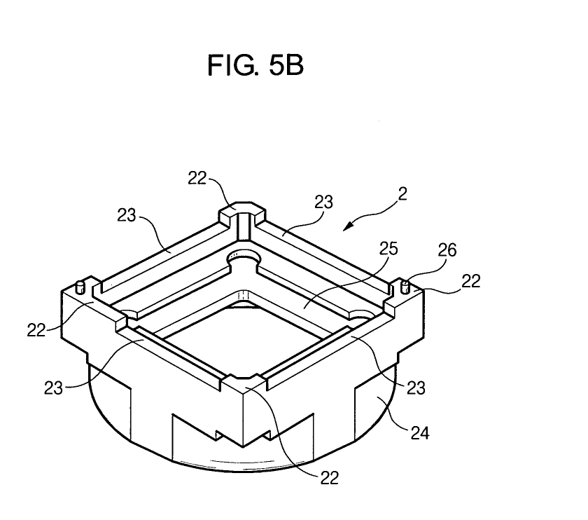

FIG. 5A is a plan view illustrating a PCB 1 in which an image sensor 10 according to a second modified embodiment of the invention is electrically connected by wire bonding sections 11, and FIG. 5B is a perspective bottom view illustrating a housing 2 which is joined on the PCB 1 of FIG. 5A. Hereinafter, the descriptions overlapped with those of the above-described embodiment will be omitted.

Referring to FIG. 5A, the image sensor 10 is attached on the PCB 1, the image sensor 10 and the PCB 1 are electrically connected by the wire bonding sections 11, and the wire boding sections 11 are formed in four directions of the image sensor 10.

On the edge of the PCB 1, filling regions 31 in which the adhesive 3 is filled are formed in four directions where the wire bonding sections 11 are present, and joining regions 30 are formed in four corners of the PCB 1, that is, in the portions where the wire bonding sections 11 are not present. The joining regions 30 are joined to joining sections 22 (refer to FIG. 5B) which are the lower surfaces of the lateral walls of the housing 2 (refer to FIG. 5B).

Referring to FIG. 5B, the housing 2 has the lateral walls formed in four directions so as to be joined on the PCB 1, and step sections 23 are formed to recede in four directions on the lower surfaces of the lateral walls corresponding to the wire bonding sections 11 of the PCB 1. Further, the joining sections 22 are respectively formed in the four corners, that is, in the portions corresponding to the joining regions 30 of the PCB 1, where the wire bonding sections 11 of the PCB 1 are not present.

A camera module according to the second modified example of the present embodiment is the same as the embodiment shown in FIGS. 2A to 2C, except that the image sensor 10 is wire-bonded in four directions on the PCB 1. Further, in the second modified example, the space is increased, compared with the embodiment of the present invention. Therefore, the adhesive 3 should be additionally filled as much as the increased space.

When the wire bonding sections 11 are formed in more than three directions on the PCB 1 as in the first and second modified embodiments, the area of the joining sections 22 of the housing 2 is reduced and thus the housing 2 can be unstably supported on the PCB 1. Therefore, the joining sections 22 of the housing 2 are preferably formed in the corners of the lateral walls.

In the present embodiment and the first and second modified embodiments, the wire bonding sections 11 are formed in more than two directions on the PCB 1. However, when the wire bonding section 11 is formed in one direction of the image sensor 10 attached on the PCB 1 or the wire bonding section 11 is partly formed in several places, the housing 2 may be formed so that the step section 23 is partly formed only on the lower surface of the lateral wall of the housing 2 corresponding to the wire bonding section 11, which makes it possible to obtain the same effect.

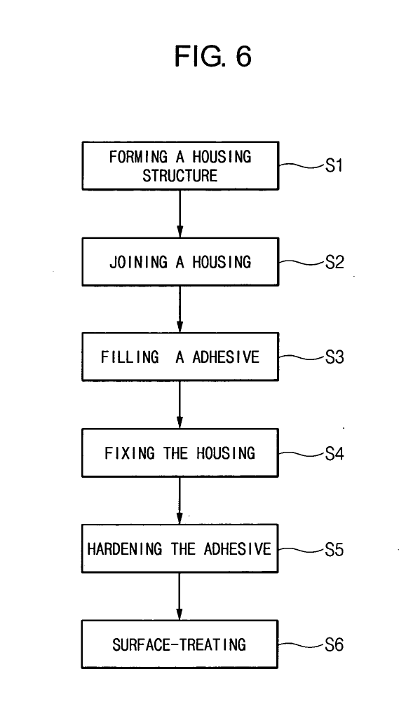

FIG. 6 is a flow chart showing a method in which the camera module according to the present invention is manufactured.

As shown in FIG. 6, the camera module according to the invention is manufactured by forming a housing structure (S1), joining a housing (S2), filling an adhesive (S3), fixing the housing (S4), hardening the adhesive (S5), and surface-treating (S6).

Hereinafter, the above manufacturing procedure will be described for each step. First, the image sensor 10 attached on the PCB 1 is electrically connected by the wire bonding sections 11, and the structure of the housing 2 which is joined to the upper portion of the PCB 1 is formed (S1).

The structure of the housing 2 is formed in the following manner. The step section 23 is formed to recede at a predetermined depth on the lower surface of the lateral wall of the housing 2 corresponding to the wire bonding section 11 of the PCB 1, and the joining section 22 is formed on the lower surface of the lateral wall of the housing 2 corresponding to the portion where the wire bonding section 11 of the PCB 1 is not formed.

Next, the adhesive 3 is applied to the joining region 30 (to which the joining section 22 of the housing 2 is joined) of the PCB 1 or the joining section 22 of the housing 2, and the housing 2 is joined on the PCB 1 (S2).

When the housing 2 and the PCB 1 are joined to each other, the space is formed between the wire bonding section 11 and the step section 23 so that the step section 23 of the housing 2 does not come in contact (wire touch) with the wire bonding section 11 in the upper side of the wire bonding section 11 of the PCB 1.

After joining the housing (S2) is completed, the black adhesive 3 is filled in the space between the wire bonding section 11 and the step section 23 in order to seal the housing 2 (S3).

The adhesive 3 filled in the space have a function of indirectly joining the step section 23 to the PCB 1 as well as blocking the space.

After filling the adhesive (S3) is completed, the housing 2 joined on the PCB 1 is pressed down by a pressing jig so as not to come off the PCB 1. In such a manner, the housing 2 is fixed to the PCB 1 (S4).

Next, in order to harden the adhesive 3 filled in the space, the PCB 1 and the housing 2 are put in an oven (not shown) which is preheated at 120° C., while being fixed by the pressing jig (not shown), and the PCB 1 and the housing 2 are thermally hardened in the oven (not shown) for about 30 minutes (S5).

Finally, after hardening the adhesive (S5) is completed, the adhesive 3, which is exposed outside the space at the time of filling the adhesive (S3) and is hardened at the time of hardening the adhesive (S5), is removed by a cutting jig, and simultaneously the lateral surface of the housing 2 can be surface-treated so as to be flattened (S6). The reason why surface-treating is performed is as follows. When the adhesive 3 is exposed outside the space, the size of the camera module becomes large as much as the thickness of the adhesive 3 exposed outside the space. As a result, when the camera module is installed inside a product, a space as large as the thickness of the adhesive 3 is occupied, and thus the limited space cannot be effectively utilized.

Surface-treating (S6) not only can be performed in manufacturing a single camera module, but also can performed in manufacturing a plurality of camera modules arranged on one PCB 1.

Therefore, even when the image sensors 10 are arranged on the PCB 1 in order to manufacture a large number of camera modules, a plurality of camera modules can be manufactured in accordance with the above-described processes. Further, when hardening an adhesive 3 is completed, the respective camera modules are separated from the PCB 1 through the singulation process, and simultaneously the adhesive 3 which is exposed outside the space so as to be hardened can be removed by a cutting jig (not shown) (S6).

In the camera module according to the present invention as described above, the lateral walls of the housing joined on the PCB are formed to be as close as possible to the image sensor electrically connected to the PCB by the wire bonding sections, the step sections are formed to recede on the lower surfaces of the lateral walls of the housing corresponding to the wire bonding sections, the housing is joined on the PCB so that the step sections do not come in contact with the wire bonding sections, and the black adhesive is filled in the space between the step section and the wire bonding section, which makes it possible to manufacture a more miniaturized camera module than a conventional camera module by using a standardized image sensor. In other words, the size of the housing and PCB of the camera module according to the present invention is reduced as much as the joining region (pad) outside the wire bonding section of the PCB according to the related art, to which the lateral wall of the housing is joined. Therefore, the camera module can be miniaturized.

Further, when the outside portion of the PCB to which the housing is joined is removed, a miniaturized single camera module can be manufactured. Therefore, when the camera module is built in a small product, the limited inner space can be effectively utilized.

Furthermore, when the outside portion of the PCB to which the housing is joined is not removed, a larger number of other parts, such as passive elements and chips, can be mounted in the spare portion of the PCB, which makes it possible to make the camera module multifunctional and complex.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A camera module comprising:
a PCB to which an image sensor is connected by a wire bonding section; and
a housing that holds a lens section, the housing including:
a joining section that is joined to the side where the wire bonding section of the PCB is not formed; and
a step section that is formed to recede in a portion corresponding to the wire bonding section of the PCB.

2. The camera module according to claim 1 further comprising
an adhesive that joins the PCB to the joining section of the housing and that fills the space between the wire bonding section and the step section of the housing.

3. A method of manufacturing a camera module comprising:
forming a step section of a housing in a portion corresponding to a wire bonding section of a PCB, the step section being formed to recede, and forming a joining section of the housing in a portion corresponding to the side where the wire bonding section of the PCB is not formed;
joining the housing onto the PCB by applying an adhesive to the joining section; and
filling the adhesive in the space between the wire bonding section and the step section.

4. The method of manufacturing a camera module according to claim 3 further comprising
fixing the housing to the PCB by using a pressing jig after filling the adhesive.

5. The method of manufacturing a camera module according to claim 4 further comprising
thermally hardening the adhesive filled in the space, with the housing and PCB being fixed by the pressing jig, after fixing the housing.

6. The method of manufacturing a camera module according to claim 5 further comprising
flattening the lateral surface of the housing by using a cutting jig in order to remove the adhesive exposed outside the space between the wire bonding section and the step section of the housing after thermally hardening the adhesive.
